(19) United States
(12) Patent Application Publication
(10) Pub. No.: US 2013/0298398 A1
(43) Pub. Date: Nov. 14, 2013

(54) PHOTOSENSITIVE RESIN COMPOSITION, PHOTOSENSITIVE ELEMENT, METHOD FOR FORMING RESIST PATTERN, AND METHOD FOR MANUFACTURING PRINTED WIRING BOARD

(71) Applicants: Masahiro Miyasaka, Hitachi-shi (JP); Masaki Endou, Hitachi-shi (JP); Masataka Kushida, Hitachi-shi (JP); Yukiko Muramatsu, Hitachi-shi (JP); Makoto Kaji, Chiyoda-ku (JP)

(72) Inventors: Masahiro Miyasaka, Hitachi-shi (JP); Masaki Endou, Hitachi-shi (JP); Masataka Kushida, Hitachi-shi (JP); Yukiko Muramatsu, Hitachi-shi (JP); Makoto Kaji, Chiyoda-ku (JP)

(21) Appl. No.: 13/885,442

(22) PCT Filed: Nov. 15, 2011
(86) PCT No.: PCT/JP2011/076296

§ 371 Date: Jul. 24, 2013

(30) Foreign Application Priority Data
Nov. 17, 2010 (JP) 2010-256922

(51) Int. Cl. G03F 7/004; H05K 3/10

(52) U.S. Cl. CPC G03F 7/004; H05K 3/10
USPC 29/846; 430/285.1; 430/325

(57) ABSTRACT

The invention relates to a photosensitive resin composition comprising a binder polymer having a (meth)acrylic acid-based structural unit, with a dispersity (weight-average molecular weight/number-average molecular weight) of no greater than 1.6, a photopolymerizable compound, a photopolymerization initiator and a sensitizing dye.

### TECHNICAL FIELD

The present invention relates to a photosensitive resin composition, and to a photosensitive element, a method for forming a resist pattern and a method for manufacturing a printed wiring board, that employ the same.

### BACKGROUND ART

Photosensitive resin compositions are widely used as resist materials for etching and plating in the field of printed wiring board manufacturing. A photosensitive resin composition is usually used as a photosensitive element (laminated body) comprising a support film and a layer formed using the photosensitive resin composition on the support film (hereunder referred to as “photosensitive resin composition layer”).

A printed wiring board may be manufactured, for example, in the following manner. First, the photosensitive resin composition layer of the photosensitive element is laminated onto a circuit-forming board (lamination step). Next, after releasing away the support film, active light rays are irradiated onto prescribed sections of the photosensitive resin composition layer to cure the exposed sections (exposure step). Next, the unexposed sections are removed (developed) from the board so that a resist pattern composed of the cured photosensitive resin composition is formed on the board (developing step). After etching treatment or plating treatment of the obtained resist pattern to form a circuit on the board (circuit-forming step), the resist is finally released off to produce a printed wiring board (releasing step).

The method of exposure employed in the past has been exposure through a photomask, with a mercury lamp as the light source. In recent years, direct writing exposure methods have been proposed, known as DLP (Digital Light Processing) or LDI (Laser Direct Imaging), wherein the digital data of a pattern is directly drawn onto a photosensitive resin composition layer (see Non Patent Literature 1, for example). Direct writing exposure method has more satisfactory positioning precision than exposure through photomasks, while high-definition patterns can also be obtained, and it is therefore being introduced for formation of high-density package boards.

The exposure time during the exposure step must be shortened to improve production efficiency. In such direct writing exposure methods, however, the light source uses monochromatic light such as a laser and the light rays are irradiated while scanning the board, and therefore a longer exposure time tends to be necessary in comparison to conventional exposure methods through photomasks. Therefore, in order to shorten the exposure time and increase production efficiency, it is essential to increase the sensitivity of photosensitive resin compositions over the prior art.

In the releasing step, the resist release time must be shortened for improved production efficiency. In addition, the size of the release strips must be reduced in order to prevent re-attachment of resist release strips onto circuit boards and increase production yields. Thus, a demand exists for a photosensitive resin composition with excellent post-curing release properties (release time and release strip sizes).

Furthermore, with increasingly higher densities of printed wiring boards in recent years, demand has also been increasing for a photosensitive resin composition with excellent resolution (resolving power) and adhesiveness. Particularly for fabrication of package boards, there is a demand for a photosensitive resin composition that can form resist patterns with L/S (line width/space width) values of 10/10 (units: μm) and smaller.

In high-density package boards it is also important for, the resist shape to be excellent, because of the narrow widths between circuits. If the cross-sectional shape of the resist is trapezoidal or reverse trapezoidal, or the resist has bottom trailing, the circuit formed by the subsequent etching treatment or plating treatment may exhibit shorting or wire breakage. Therefore, it is preferable that the resist shape has a rectangular cross-section with no bottom trailing.

Various photosensitive resin compositions have been investigated in the past with the aim of meeting this demand, for example, Patent Literatures 1-3 disclose photosensitive resin compositions with improved sensitivity, that employ specific sensitizing dyes.

### CITATION LIST

### Patent Literature

Patent Literature 1: 2007-279381 A
Patent Literature 2: WO 2007/004619 A
Patent Literature 3: JP 2009-003177 A
Patent Literature 4: JP 11-327137 A
Patent Literature 5: JP 2009-19165 A

### Non Patent Literature

Non Patent Literature 1: Yoneda, “Advantages of laser direct writing, and digitalization of PCB production process”, Electronics Jissou Gijutsu, June 2002, p 34-79

### SUMMARY OF INVENTION

### Technical Problem

Conventional photosensitive resin compositions, however, have been in need of improvement in terms of resolution, adhesiveness or resist shape. In particular, because it has been difficult to obtain photosensitive resin compositions capable of forming resist patterns with L/S (line width/space width) values of 10/10 (unit: μm) or smaller, there remains a strong need to increase the resolution and adhesiveness of photosensitive resin compositions by 1 μm units, while satisfying the other properties.

It is therefore an object of the invention to provide photosensitive resin composition that is satisfactory from the viewpoint of sensitivity, resolution, adhesiveness, resist shape and post-curing release properly, as well as a photosensitive element, a method for forming a resist pattern and a method for manufacturing a printed wiring hoard, which employ the same.

### Solution to Problem

As a result of much diligent research aimed at solving the problems described above, the present inventors have found that it is possible to obtain a photosensitive resin composition that is satisfactory from the viewpoint of sensitivity, resolution, adhesiveness, resist shape and post-curing release property, by using a binder polymer with a dispersity (weight-average molecular weight/number-average molecular weight) of no greater than 1.6, and the invention has been completed upon this finding.

Specifically, the invention provides a photosensitive resin composition comprising a binder polymer having a (meth)acrylic acid-based structural unit, with a dispersity of no greater than 1.6, a photopolymerizable compound, a photopolymerization initiator and a sensitizing dye.

The photosensitive resin composition of the invention which combines a specific binder polymer and a sensitizing dye with a photopolymerizable compound and a photopolymerization initiator is not only satisfactory in terms of sensitivity, resist shape and post-curing release property, but is also superior in terms of resolution and adhesiveness. The photosensitive resin composition of the invention allows formation of resist patterns with L/S (line width/space width) values of 10/10 (units: μm) and smaller.

The binder polymer may also have a structural unit based on at least one type of polymerizable monomer selected from the group consisting of benzyl (meth)acrylate, benzyl (meth)acrylate derivatives, styrene and styrene derivatives. This can further improve the resolution and adhesiveness.

The acid value of the binder polymer is preferably 90 to 250 mgKOH/g, and the weight-average molecular weight of the binder polymer is preferably 10000 to 100000. This can further improve the balance between alkali developing property, developing time and developing solution resistance (adhesiveness).

The photopolymerizable compound may contain a bisphenol A-based di(meth)acrylate compound. This can further improve the alkali developing property, resolution and post-curing release property.

If the photopolymerization initiator contains a 2,4,5-triarylimidazole dimer, the sensitivity, resolution and adhesiveness can be further improved.

From the viewpoint of further improving sensitivity, the photosensitive resin composition of the invention may further contain an amine-based compound.

The invention provides a photosensitive element comprising a support film and a photosensitive resin composition layer formed using the aforementioned photosensitive resin composition, on the support film. By using such a photosensitive element, it is possible to efficiently form a resist pattern with especially excellent resolution, adhesiveness and resist shape, with high sensitivity.

The invention also provides a method for forming a resist pattern that comprises a lamination step in which a photosensitive resin composition layer formed using the aforementioned photosensitive resin composition is laminated on a substrate, an exposure step in which prescribed sections of the photosensitive resin composition layer are irradiated with active light rays for exposure and curing of the prescribed sections, and a developing step in which the sections other than the prescribed sections of the photosensitive resin composition layer are removed from the board to form a resist pattern composed of the cured photosensitive resin composition on the substrate. This method allows highly sensitive and efficient formation of a resist pattern which is satisfactory from the viewpoint of resolution, adhesiveness, resist shape and post-curing release property.

In this method for forming a resist pattern, the wavelength of the irradiated active light rays is preferably in the range of 340 to 430 nm. This will allow even more highly sensitive and efficient formation of a resist pattern that is more satisfactory from the viewpoint of resolution, adhesiveness and resist shape.

The invention further provides a method for manufacturing a printed wiring hoard that comprises a step of etching or plating the substrate on which a resist pattern has been formed by the method described above. With this manufacturing method it is possible to precisely and efficiently produce a printed wiring board with high-density wiring, such as a high-density package board.

### Advantageous Effects of Invention

According to the invention it is possible to provide a photosensitive resin composition that is satisfactory from the viewpoint of sensitivity, resolution, adhesiveness, resist shape and post-curing release property, as well as a photosensitive element, a method for forming a resist pattern and a method for manufacturing a printed wiring board, which employ the same.

### BRIEF DESCRIPTION OF DRAWINGS

FIG. 1 is a schematic cross-sectional view showing a preferred embodiment of a photosensitive element of the invention.

### DESCRIPTION OF EMBODIMENTS

Embodiments for carrying out the invention will now be explained in further detail. However, the present invention is not limited to the embodiments described below. Throughout the present specification, “(meth)acrylic acid” refers to acrylic acid or methacrylic acid, “(meth)acrylate” refers to acrylate or methacrylate, and “(meth)acryloyl group” refers to an acryloyl or methacryloyl group. Also, “(poly)oxyethylene chain” refers to an oxyethylene or polyoxyethylene chain, and “(poly)oxypropylene chain” refers to an oxypropylene or polyoxypropylene chain. Furthermore, the term “EO-modified” refers to a compound with a (poly)oxyethylene chain, the term “PO-modified” refers to a compound with a (poly)oxypropylene chain, and “EO PO-modified” refers to a compound with both a (poly)oxyethylene chain and a (poly)oxypropylene chain.

(Photosensitive Resin Composition)

The photosensitive resin composition of this embodiment comprises a binder polymer having a (meth)acrylic acid-based structural unit, with a dispersity of no greater than 1.6, a photopolymerizable compound, a photopolymerization initiator and a sensitizing dye.

<Binder Polymer>

The binder polymer having a (meth)acrylic acid-based structural unit and a dispersity of no greater than 1.6 (hereunder referred to as “component (A)” or “(A) binder polymer”) will be explained first.

Throughout the present specification, the term “dispersity” refers to the ratio of the weight-average molecular weight (Mw) to the number-average molecular weight (Mn) (Mw/Mn). It is sufficient if the dispersity (Mw/Mn) of the binder polymer is no greater than 1.6, but from the viewpoint of excellent adhesiveness and resolution, it is preferably no greater than 1.58 and more preferably no greater than 1.55. The lower limit for the dispersity is not particularly restricted, but will usually be at least 1.

Component (A) may be used without any particular restrictions so long as it is a binder polymer having a (meth)acrylic acid-based structural unit and a dispersity of no greater than 1.6. Component (A) is obtained, for example, by radical polymerization of a polymerizable monomer containing (meth)acrylic acid. The dispersity of the binder polymer can be adjusted by the reaction temperature or the reaction time for synthesis, or the amount of initiator addition.

Examples of polymerizable monomers (monomers) include (meth)acrylic acid; (meth)acrylic acid esters such as alkyl (meth)acrylate esters, benzyl (meth)acrylate, benzyl (meth)acrylate derivatives, furfuryl (meth)acrylate, tetrahydrofurfuryl (meth)acrylate, isobornyl (meth)acrylate, adamantyl (meth)acrylate, dicyclopentanyl (meth)acrylate, dimethylaminoethyl (meth)acrylate, diethylaminoethyl (meth)acrylate, glycidyl (meth)acrylate, 2,2,2-trifluoroethyl (meth)acrylate, 2,2,3,3-tetrafluoropropyl (meth)acrylate, α-bromo (meth)acrylic acid, α-chloro (meth)acrylic acid, β-furyl (meth)acrylic acid and β-styryl (meth)acrylic acid; styrene; polymerizable styrene derivatives substituted at the α-position or on the aromatic ring, such as vinyltoluene or α-methylstyrene, acrylamides such as diacetoneacrylamide; acrylonitrile; vinyl alcohol esters such as vinyl-n-butyl ether; maleic acid; maleic anhydride; maleic acid monoesters such as monomethyl malate, monoethyl malate and monoisopropyl malate; and fumaric acid, cinnamic acid, α-cyanocinnamic acid, itaconic acid, crotonic acid and propiolic acid. These may be used alone or in any desired combinations of two or more.

Of these polymerizable monomers, component (A) is preferably one having a structural unit based on at least one type of polymerizable monomer selected from the group consisting of benzyl (meth)acrylate, benzyl (meth)acrylate derivatives, styrene and styrene derivatives, from the viewpoint of satisfactory resolution and adhesiveness. More preferably, it contains both at least one unit selected from the group consisting of benzyl (meth)acrylate and benzyl (meth)acrylate derivatives, and at least one unit selected from the group consisting of styrene and styrene derivatives. That is, component (A) is preferably obtained by radical polymerization of these polymerizable monomers, and preferably it has a structural unit derived from these polymerizable monomers.

When component (A) has a structural unit based on benzyl (meth)acrylate or a derivative thereof, from the viewpoint of excellent resolution and release property, the content is preferably 5 to 80 wt %, more preferably 10 to 70 wt % and even more preferably 20 to 60 wt %, based on the total weight (total molecular weight) of the polymerizable monomer composing component (A). From the viewpoint of excellent resolution, the content is preferably at least 5 wt %, and in order to shorten the release time the content is preferably no greater than 80 wt %.

When component (A) has a structural unit based on styrene or a derivative thereof, from the viewpoint of excellent adhesiveness and release property, the content is preferably 10 to 70 wt %, more preferably 20 to 60 wt % and even more preferably 30 to 50 wt %, based on the total weight of the polymerizable monomer composing component (A). From the viewpoint of excellent adhesiveness, the content is preferably at least 10 wt %, and from the viewpoint of excellent release property, the content is preferably no greater than 70 wt %.

Also, component (A) preferably has a structural unit based on an alkyl (meth)acrylate ester, from the viewpoint of improving the alkali developing property and release property.

When component (A) has a structural unit based on an alkyl (meth)acrylate ester, from the viewpoint of excellent release property, resolution and adhesiveness, the content is preferably 1 to 30 wt %, more preferably 2 to 20 wt % and even more preferably 3 to 10 wt %, based on the total weight of the polymerizable monomer composing component (A). From the viewpoint of an excellent release property, the content is preferably at least 1 wt %, and from the viewpoint of excellent resolution and adhesiveness, the content is preferably no greater than 30 wt %.

The alkyl (meth)acrylate ester may be a compound represented by the following general formula (1). In the following general formula (1), R¹ represents hydrogen or a methyl group, and R² represents a C1-12 alkyl group,

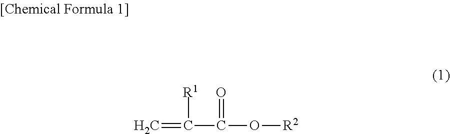

Examples of C1-1 alkyl groups represented by R² in the general formula (1) include methyl, ethyl, propyl, butyl, pentyl, hexyl, heptyl, octyl, nonyl, decyl, undecyl, dodecyl, and their structural isomers. From the viewpoint of further improving the release property, the alkyl group is preferably no greater than C4.

Examples of compounds represented by the general formula (1) include methyl (meth)acrylate, ethyl (meth)acrylate, propyl (meth)acrylate, butyl (meth)acrylate, pentyl (meth)acrylate, hexyl (meth)acrylate, heptyl (meth)acrylate, octyl (meth)acrylate, 2-ethylhexyl (meth)acrylate, nonyl (meth)acrylate, decyl (meth)acrylate, undecyl (meth)acrylate and dodecyl (meth)acrylate. These may also be used alone or in any desired combinations of two or more.

The acid value of component (A) is preferably 90 to 250 mgKOH/g, more preferably 100 to 230 mgKOH/g, even more preferably 110 to 210 mgKOH/g and most preferably 120 to 200 mgKOH/g, from the viewpoint of excellent developability and developing solution resistance. From the viewpoint of excellent developability, the acid value is preferably at least 90 mgKOH/g, while from the viewpoint of developing solution resistance (adhesiveness) of the cured product, it is preferably no greater than 250 mgKOH/g. When solvent development is to be carried out, it is preferred to reduce the amount of the carboxyl group-containing polymerizable monomers such as (meth)acrylic acid.

The weight-average molecular weight (Mw) of component (A) is preferably 10,000 to 100000, more preferably 20000 to 80000 and even more preferably 25000 to 70000, as measured by gel permeation chromatography (GPC) (based on a calibration curve using standard polystyrene), from the viewpoint of excellent developability and developing solution resistance. From the viewpoint of excellent developing solution resistance (adhesiveness) of the cured photosensitive resin composition, the weight-average molecular weight (Mw) is preferably 10000 or greater, while from the viewpoint or excellent developability it is preferably no greater than 100000.

If necessary, component (A) may have in the molecule characteristic groups with photosensitivity for light in a wavelength range of 340 to 430 nm.

Component (A) may be used as a single binder polymer alone, or it may be used as any desired combination of two or more binder polymers. Examples of binder polymers employing combinations of two or more types include two or more binder polymers composed of different copolymerizing components (including those having different monomer units as copolymerizing components), two or more binder polymers with different weight-average molecular weights, and two or more binder polymers with different dispersities. There may also be used a polymer having a multimode molecular weight distribution, as described in Patent Literature 4 (JP 11-327137 A).

From the viewpoint of excellent film formability, sensitivity and resolution, the content of component (A) is preferably 30 to 70 parts by weight, more preferably 35 to 65 parts by weight and most preferably 40 to 60 parts by weight, with respect to 100 parts by weight as the total of component (A) and component (B). If the content is at least 30 parts by weight it will tend to be easier to form a film (photosensitive resin composition layer), and if it is no greater than 70 parts by weight, it will tend to be easier to obtain sufficient sensitivity and resolution,

<Photopolymerizable Compound>

The photopolymerizable compound (hereunder, “component (B)”) will now be explained.

Component (B) is not par particularly restricted so long as it is photo-crosslinkable, and it may be a compound with an ethylenic unsaturated bond. Compounds with ethylenic unsaturated bonds include compounds having one ethylenic unsaturated bond in the molecule, compounds having two ethylenic unsaturated bonds in the molecule and the like.

Component (B) preferably contains a compound with two ethylenic unsaturated bonds in the molecule at 10 to 80 wt % and more preferably 30 to 70 wt % with respect to the total weight of component (B).

Examples of compounds with, two ethylenic unsaturated bonds in the molecule include bisphenol A-based di(meth)acrylate compounds, and polyalkylene glycol di(meth)acrylate compounds having both a (poly)oxyethylene chain and a (poly)oxypropylene chain in the molecule.

Among these, component (B) preferably contains a bisphenol A-based di(meth)acrylate compound from the viewpoint of improving the resolution and release property.

Bisphenol A-based di(meth)acrylate compounds include compounds represented by the following general formula (2).

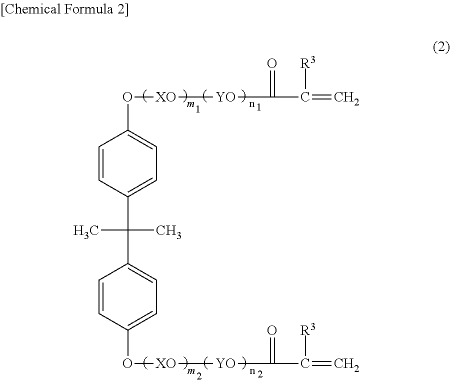

In the general formula (2), R³ and R⁴ each independently represent hydrogen or a methyl group. XO and YO each independently represent an oxyethylene or oxypropylene group, (XO)m₁, (XO)m₂, (YO)n₁ and (YO)n₂ each independently represent a (poly)oxyethylene chain or (poly)oxypropylene chain. The symbols m₁, m₂, n₁ and n₂ each independently represent an integer of 0 to 40. When XO is an oxyethylene group and YO is an oxypropylene group, m₁+m₂ is between 1 and 40 and n₁+n₂ is between 0 and 20, and when XO is an oxypropylene group and YO is an oxyethylene group, m₁+m₂ is between 0 and 20 and n₁+n₂ is between 1 and 40,

The compound represented by the general formula (2) may be used alone or in any combination of two or more types, but preferably two or more types are used in combination, depending on the sensitizing dye as explained below.

Specifically, when used in combination with sensitizing dyes such as pyrazoline compounds, coumarin compounds, thioxanthone compounds or aminoacridine compounds, from the viewpoint of excellent sensitivity and resolution it is preferred to use a combination of a compound with an oxyethylene chain number (m₁+m₂ or n₁+n₂) of 0 to 5 and a compound with an oxyethylene chain number of 5 to 40, and more preferably it is preferred to use a combination of a compound with an oxyethylene chain number of 0 to 5 and a compound with an oxyethylene chain number of 5 to 15, in the compound represented by the general formula (2).

Of the compounds represented by the general formula), 2,2-bis(4-(methacryloyloxypentaethoxy)phenyl)propane is commercially available as BPE-500 (trade name of Shin-Nakamura Chemical Co., Ltd.) or FA-321M (trade name of Hitachi Chemical Co., Ltd.), and 2,2-bis(4-(methacrloyloxypentadecaethoxy)phenyl)propane is commercially available as BPB-1300 (trade name of Shin-Nakamura Chemical Co., Ltd.). These may be used alone or in any combinations of two or more.

Component (B) preferably contains a polyalkylene glycol di(meth)acrylate, from the viewpoint of improving the flexibility and resolution of the cured photosensitive resin composition (cured film). The polyalkylene glycol di(meth)acrylate content is preferably 5 to 50 wt % and more preferably 10 to 40 wt % with respect to the total amount of component (13).

The polyalkylene glycol di(meth)acrylate is preferably a polyalkylene glycol di(meth)acrylate having both a (poly)oxyethylene chain and a (poly)oxypropylene chain in the molecule. The (poly)oxyethylene chain and (poly)oxypropylene chain in the polyalkylene glycol di(meth)acrylate molecule may each be present in a continuous block form, or be present in random form. The oxypropylene group of the (poly)oxypropylene chain may be either an oxy-n-propylene or oxyisopropylene group. Also, the secondary carbon of the propylene group in the (poly)oxyisopropylene chain may be bonded to an oxygen atom, or the primary carbon may be bonded to an oxygen atom.

The polyalkylene glycol di(meth)acrylate may further have a (poly)oxy-n-butylene chain, (poly)oxyisobutylene chain, (poly)oxy-n-pentylene chain, (poly)oxyhexylene chain, or an approximately C4-6 (poly)oxyalkylene chain which is a structural isomer of the foregoing.

Particularly preferred polyalkylene glycol di(meth)acrylates are compounds represented by the following general formulas (3), (4) and (5). These may be used alone or in combinations of two or more.

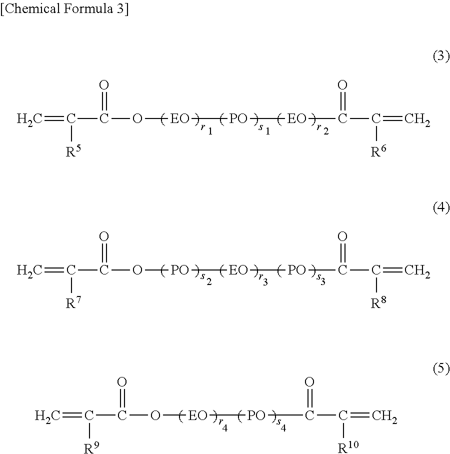

In formulas (3), (4) and (5), R⁵ to R¹⁰ each independently represent hydrogen or a methyl group. EC) represents an oxyethylene group, and PO represents an oxypropylene group. The denotations r₁, r₂, r₃ and r₄ represent the number of repeating structural units composed of oxyethylene groups, and the denotations s₁, s₂, s₃ and s₄ represent the number of repeating structural units composed of oxypropylene groups. The total numbers of repeating oxyethylene groups r₁+r₂, r₃ and r₄ (mean value) each independently represent an integer of 1 to 30, and the total numbers of repeating oxypropylene groups s₁, s₂+s₃ and s₄ (mean value) each independently represent an integer of 1 to 30.

In the compounds represented by the general formulas (3), (4) and (5), the total numbers of repeating oxyethylene groups r₁+r₂, r₃ and r₄ are each an integer of 1 to 30, preferably an integer of 1 to 10, more preferably an integer of 4 to 9 and most preferably an integer of 5 to 8. If the total number of repeats exceeds 30, it will tend to be difficult to obtain satisfactory resolution, adhesiveness and resist shape.

The total number of repeating oxypropylene groups s₁, s₂+s₃ and s₄ are each an integer of 1 to 30, preferably an integer of 5 to 20, more preferably an integer of 8 to 16 and most preferably an integer of 10 to 14. If the total number of repeats exceeds 30, it will tend to be difficult to obtain satisfactory resolution, and sludge will tend to be easily generated.

The compound represented by the general formula (3) may be a vinyl compound in which R⁵ and R⁶=methyl, r₁+r₂=6 (mean value) and s₁=12 (mean value) (“FA-023M”, trade name of Hitachi Chemical Co., Ltd.). The compound represented by the general formula (4) may be a vinyl compound in which R⁷ and R⁸=methyl, r₃=6 (mean value) and s₂+s₃=12 (mean value) (“FA-024M”, trade name of Hitachi Chemical Co., Ltd.). The compound represented by the general formula (5) may be a vinyl compound in which R⁹ and R¹⁰=hydrogen, r₄=1 (mean value) and s₄=9 (mean value) (sample name: “MK. Ester HEMA-9P”, by Shin-Nakamura Chemical Co., Ltd.). These may be used alone or in combinations of two or more.

Also, from the viewpoint of satisfactory balance between resolution, adhesiveness, resist shape and post-curing release property, component (B) may contain a photopolymerizable compound with one ethylenic unsaturated bond in the molecule. In this case, the content of the photopolymerizable compound with one ethylenic unsaturated bond in the molecule is preferably 1 to 30 wt %, more preferably 3 to 25 wt. % and even more preferably 5 to 20 wt % based on the total weight of component (B).

Examples of compounds with one ethylenic unsaturated bond in the molecule include nonylphenoxypolyethylene oxyacrylates, phthalle acid-based compounds and alkyl (meth)acrylate esters.

Of these, it preferably contains a nonylphenoxypolyethylene oxyacrylate or a phthalic acid-based compound from the viewpoint of satisfactory balance between resolution, adhesiveness, resist shape and post-curing release property.

Examples of nonylphenoxypolyethylene oxyacrylates include nonylphenoxytriethylene oxyacrylate, nonylphenoxytetraethylene oxyacrylate, nonylphenoxypentaethylene oxyacrylate, nonylphenoxyhexaethylene oxyacrylate, nonylphenoxyheptaethylene oxyacrylate, nonylphenoxyoctaethylene oxyacrylate, nonylphenoxynonaethylene oxyacrylate, nonylphenoxydecaethylene oxyacrylate and nonylphenoxyundecaethylene oxyacrylate. These may also be used alone or in any desired combinations of two or more. A “nonylphenoxypolyethylene oxyacrylate” may also be referred to as “nonylphenoxypolyethylene glycol acrylate”.

Of these, nonylphenoxyoctaethylene oxyacrylate is commercially available as M-114 (trade name of Toagosei Co., Ltd., 4-normal nonylphenoxyoctaethylene oxyacrylate). The compound “4-normal nonylphenoxyoctaethylene oxyacrylate” may also be referred to as “4-normal nonylphenoxyoctaethylene glycol acrylate”.

Examples of phthalic acid-based compounds include γ-chloro-β-hydroxypropyl-β′-(meth)acryloyloxyethyl-o-phthalate, β-hydroxyethyl-β′-(meth)acryloyloxyethyl-o-phthalate and β-hydroxypropyl-β′-(meth)acryloyloxyethyl-o-phthalate, among which γ-chloro-β-hydroxypropyl-β′-(meth)acryloyloxyethyl-o-phthalate is preferred. The compound γ-chloro-β-hydroxypropyl-β′-methacryloyloxyethyl-o-phthalate is commercially available as FA-MECH (trade name of Hitachi Chemical Co., Ltd.). These may be used alone or in combinations of two or more.

The total content of component (B) is preferably 30 to 70 parts by weight, more preferably 35 to 65 parts by weight and most preferably 35 to 60 parts by weight, with respect to 100 parts by weight as the total of component (A) and component (B). If the content is at least 30 parts by weight it will tend to be easier to obtain sufficient sensitivity and resolution, and if it is no greater than 70 parts by weight it will tend to be easier to form a film, and it will tend to be easier to obtain a satisfactory resist shape.

<Photopolymerization Initiator>

The photopolymerization initiator (hereunder, “component (C)”) will now be explained.

There are no particular restrictions on the photopolymerization initiator as component (C), and examples include aromatic ketones such as benzophenone and 2-benzyl-2-dimethylamino-1-(4-morpholinophenyl)-butanone-1,2-meth yl-1-[4-(methylthio)phenyl]-2-morpholino-propanone-1; quinones such as alkylanthraquinone; benzoinether compounds such as benzoinalkyl ethers; benzoin compounds such as benzoin and alkylbenzoins; benzyl derivatives such as benzyldimethylketal; 2,4,5-triarylimidazole dimers such as 2-(o-chlorophenyl)-4,5-diphenylimidazole dimer and 2-(o-fluorophenyl)-4,5-diphenylimidazole dimer; and acridine derivatives such as 9-phenylacridine and 1,7-(9,9′-acridinyl)heptane. These may be used alone or in combinations of two or more.

Component (C) preferably includes a 2,4,5-triarylimidazole dimer, and more preferably a 2-(o-chlorophenyl)-4,5-diphenylimidazole dimer, from the viewpoint of improving the sensitivity and adhesiveness. The 2,4,5-triarylimidazole dimer may have either a symmetrical or asymmetrical structure.

The content of component (C) is preferably 0.1 to 10 parts by weight, more preferably 1 to 7 parts by weight, even more preferably 2 to 6 parts by weight and most preferably 3 to 5 parts by weight, with respect to 100 parts by weight as the total of component (A) and component (B). A content of at least 0.1 part by weight will tend to more easily result in satisfactory sensitivity, resolution and adhesiveness, while a content of no greater than 10 parts by weight will tend to more easily produce a satisfactory resist shape.

<Sensitizing Dye>

The sensitizing dye (hereunder, “component (D)”) will now be explained.

Examples of sensitizing dyes as component (D) include dialkylaminobenzophenone compounds, pyrazoline compounds, anthracene compounds, coumarin compounds, xanthone compounds, thioxanthone compounds, oxazole compounds, benzooxazole compounds, thiazole compounds, benzothiazole compounds, triazole compounds, stilbene compounds, triazine compounds, thiophene compounds, naphthalimide compounds, triarylamine compounds and aminoacridine compounds. These may be used alone or in combinations of two or more.

Particularly when a photosensitive resin composition layer is exposed using active light rays of 340 to 430 nm, component (D) preferably includes at least one type of sensitizing dye selected from the group consisting of dialkylaminobenzophenone compounds, pyrazoline compounds, anthracene compounds, coumarin compounds, triarylamine compounds, thioxanthone compounds and aminoacridine compounds, from the viewpoint of sensitivity and adhesiveness. Of these, it more preferably contains at least one type of sensitizing dye selected from the group consisting of pyrazoline compounds, anthracene compounds, coumarin compounds, triarylamine compounds, thioxanthone compounds and aminoacridine compounds, and even more preferably it contains a pyrazoline compound, anthracene compound or triarylamine compound.

The content of component (D) is preferably 0.01 to 10 parts by weight, more preferably 0.05 to 5 parts by weight and most preferably 0.1 to 3 parts by weight with respect to 100 parts by weight as the total of component (A) and component (B). From the viewpoint of excellent sensitivity and resolution, the content is preferably at least 0.01 part by weight, and in order to obtain a satisfactory resist shape, it is preferably no greater than 10 parts by weight.

The aforementioned pyrazoline compound may be a compound represented by the following general formula (6) or (1),

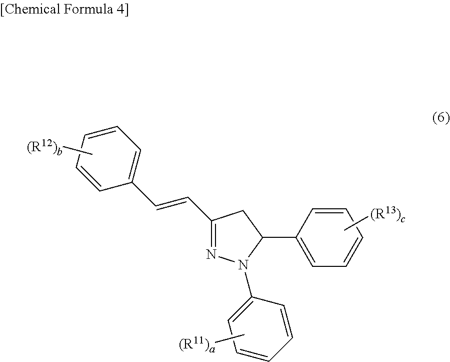

In the general formula (6), R¹¹ to R¹³ each independently represent a C1-12 straight-chain or branched alkyl group, a C1-10 straight-chain or branched alkoxy group or a halogen atom. Also, a, b and c each independently represent an integer of 0 to 5, and the total of a, b and c being from 1 to 6. When the total of a, b and c is 2 or greater, the multiple R¹¹ to R¹³ groups may be the same or different

At least one of R¹¹ to R¹³ in the general formula (6) is preferably a C1-12 straight-chain or branched alkyl group or a C1-10 straight-chain or branched alkoxy group, more preferably a C1-3 straight-chain or branched alkyl group or a C1-3 straight-chain or branched alkoxy group, and even more preferably an isopropyl, methoxy or ethoxy group.

Pyrazoline compounds represented by the general formula (6) may be used without any particular restrictions, and specifically these include pyrazoline compounds wherein a=0 in the general formula (6), such as 1-phenyl-3-(4-isopropylstyryl)-5-(4-isopropylphenyl)-pyrazoline, 1-phenyl-3-(4-tert-butyl-styryl)-(4-tert-butyl)-pyrazol Me, 1-phenyl-3-(4-methoxystyryl)-5-(4-methoxyphenyl)-pyrazoline, 1-phenyl-3-(3,5-dimethoxystyryl)-5-(3,5-dimethoxyphenyl)-pyrazoline, 1-phenyl-3-(3,4-dimethoxy styryl)-5-(3,4-dimethoxyphenyl)-pyrazoline, 1-phenyl-3-(2,6-dimethoxystyryl)-5-(2,6-dimethoxyphenyl)-pyrazoline, 1-phenyl-3-(2,5-dimethoxystyryl)-5-(2,5-dimethoxyphenyl)-pyrazoline, 1-phenyl-3-(2,3-dimethoxystyryl)-5-(2,3-dimethoxyphenyl)-pyrazoline and 1-phenyl-3-(2,4-dimethoxystyryl)-5-(2,4-dimethoxyphenyl)-pyrazoline.

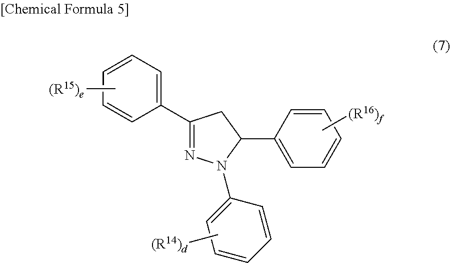

In the general formula (7), R¹⁴ to R¹⁶ each independently represent a C1-12 straight-chain or branched alkyl group, a C1-10 straight-chain or branched alkoxy group, a halogen atom or a phenyl group. Also, d, e and f each independently represent an integer of 0 to 5, and the total of d, e and f being from 1 to 6. When the total of d, e and f is 2 or greater, the multiple R¹⁴ to R¹⁶ groups may be the same or different.

At least one of R¹⁴ to R¹⁶ in the general formula (7) is preferably a C1-12 straight-chain or branched alkyl group, a C1-10 straight-chain or branched alkoxy group or a phenyl group, more preferably a C1-4 straight-chain or branched alkyl group, a C1-4 straight-chain or branched alkoxy group or phenyl group, and even more preferably a tert-butyl, isopropyl, methoxy, ethoxy or phenyl group.

The pyrazoline compound represented by the general formula (7) may be used without any particular restrictions, and examples include pyrazoline compounds wherein a=0 in the general formula (7), such its 1-phenyl-3,5-bis(4-tert-butyl-phenyl)-pyrazoline, 1-phenyl-3,5-bis(4-methoxy-phenyl)-pyrazoline, 1-phenyl-3-(4-methoxy-phenyl)-5-(4-tert-butyl-phenyl)-pyrazoline, 1-phenyl-3-(4-tert-butyl-phenyl)-5-(4-methoxy-phenyl)-pyrazoline, 1-phenyl-3-(4-isopropyl-phenyl)-5-(4-tert-butyl-phenyl)-pyrazoline, 1-phenyl-3-(4-tert-butyl-phenyl)-5-(4-isopropyl-phenyl)-pyrazoline, 1-phenyl-3-(4-methoxy-phenyl)-5-(4-isopropyl-phenyl)-pyrazoline, 1-phenyl-3-(4-isopropyl-phenyl)-5-(4-methoxy-phenyl)-pyrazoline, 1,5-diphenyl-3-(4-tert-butyl-phenyl)-pyrazoline, 1,3-diphenyl-5-(4-tert-butyl-phenyl)-pyrazoline, 1,5-diphenyl-3-(4-isopropyl-phenyl)-pyrazoline, 1,3-diphenyl-5-(4-isopropyl-phenyl)-pyrazoline, 1,5-diphenyl-3-(4-methoxy-phenyl)-pyrazoline, 1,3-diphenyl-5-(4-methoxy-phenyl)-pyrazoline, 1-phenyl-3,5-bis(4-tert-butyl-phenyl)-pyrazoline and 1,5-diphenyl-3-(4-tert-butyl-phenyl)-pyrazoline, and pyrazoline compounds wherein e=1 and R¹⁵=phenyl group in the general formula (7), such 1-phenyl-3-(4-biphenyl)-5-(4-tert-beryl-phenyl)-pyrazoline and 1-phenyl-3-(4-biphenyl)-5-(4-tert-octyl-phenyl)-pyrazoline.

The anthracene compounds mentioned above preferably include a compound represented by the following general formula (8).

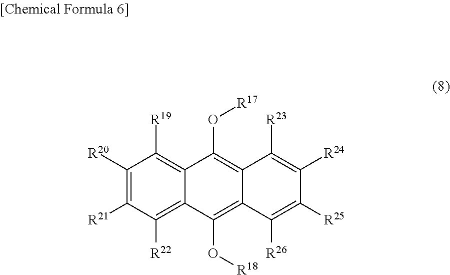

In the general formula (8), R¹⁷ and R¹⁸ each independently represent a C1-20 alkyl, C5-12 cycloalkyl, phenyl, benzyl, C2-12 alkanoyl or benzoyl group. R¹⁹, R²⁰, R²¹, R²², R²³, R²⁴, R²⁵ and R²⁶ each independently represent hydrogen, C1-12 alkyl, a halogen atom, or a cyano, carboxyl, phenyl, C2-6 alkoxycarbonyl or benzoyl group. When the aforementioned C1-20 alkyl group is a C2-12 alkyl group, it may have an oxygen atom between the main chain carbon atoms, and may be substituted with a hydroxyl group. The C5-12 cycloalkyl group may have an oxygen atom in the ring and may be substituted with a hydroxyl group. The phenyl group in R¹⁷ and R¹⁸ may be substituted with one or more groups and/or atoms selected from the group consisting of C1-6 alkyl, hydroxyl, halogen atoms, cyano, carboxy, phenyl, C1-6 alkoxy, phenoxy and C2-6 alkoxycarbonyl. The benzyl group may be substituted with one or more groups and/or atoms selected from the group consisting of C1-6 alkyl, hydroxyl, halogen atoms, cyano, carboxyl, phenyl, C1-6 alkoxy, phenoxy and C2-6 alkoxycarbonyl. The benzoyl group may be substituted with one or more groups and/or atoms selected from the group consisting of C1-6 alkyl, hydroxyl, halogen atoms, cyano, carboxyl, phenyl, C1-6 alkoxy, phenoxy and C2-6 alkoxycarbonyl.

Examples for R¹⁷ and R¹⁸ and the general formula (8) include methyl, ethyl, propyl, butyl, pentyl and hexyl. Examples of combinations of R¹⁷ and R¹⁸ include a combination of ethyl groups, a combination of propyl groups and a combination of butyl groups.

Examples for R¹⁹ to R²⁶ include hydrogen, methyl, ethyl, propyl, butyl, pentyl, hexyl, propenyl, butenyl, pentenyl, hexenyl, heptenyl, ethoxycarbonyl, hydroxyethoxycarbonyl and phenoxy. Examples of combinations of R¹⁹ to R²⁶ include all hydrogens; a combination of one group as methyl, ethyl, propyl, butyl, pentyl, hexyl, propenyl, butenyl, pentenyl, hexenyl, heptenyl, ethoxycarbonyl, hydroxyethoxycarbonyl or phenoxy and the rest hydrogens; and a combination of two groups such as methyl, ethyl, propyl, butyl, penty, hexyl, propenyl, butenyl, pentenyl, hexenyl, heptenyl, ethoxycarbonyl, hydroxyethoxycarbonyl or phenoxy, or different combinations thereof, and the rest hydrogens.

R¹⁷ and R¹⁸ are preferably C1-4 alkyl groups. R¹⁹, R²⁰, R²¹, R²², R²³, R²⁴, R²⁵ and R²⁶ are preferably hydrogens.

Specific compounds represented by the general formula (8) include 9,10-dimethoxyanthracene, 9,10-diethoxyanthracene and 9,10-dibutoxyanthracene.

The triarylamine compounds mentioned above preferably include a compound represented by the following general formula (9).

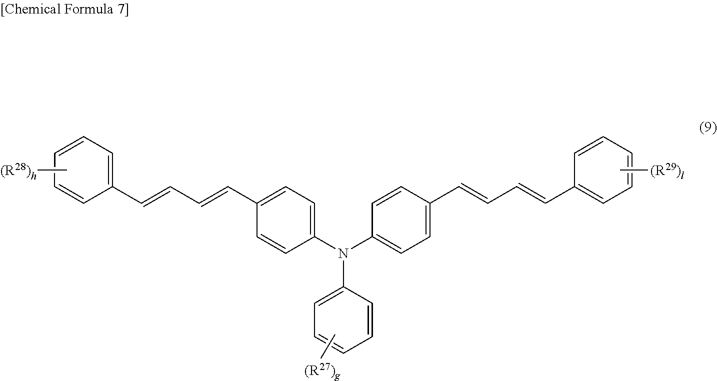

In the general formula (9), R²⁷ and R²⁹ each independently represent a C1-10 alkyl or C1-4 alkoxy group. The letters g, h and i each represent an integer of 0 to 5 selected so that the value of g+h+i is 1 or greater. When g is 2 or greater, the multiple R²⁷ groups may be the same or different, when h is 2 or greater the multiple R²⁸ groups may be the same or different, and when i is 2 or greater the multiple R²⁹ groups may be the same or different.

<Amine-Based Compound>

Examples of amine-based compounds (hereunder also referred to as “component (E)”) include bis[4-(dimethylamino)phenyl]methane, bis[4-(diethylamino)phenyl]methane and leuco crystal violet. These may be used alone or in combinations of two or more.

When the photosensitive resin composition contains component (E), the content is preferably 0.01 to 10 parts by weight, more preferably 0.05 to 5 parts by weight and most preferably 0.1 to 2 parts by weight with respect to 100 parts by weight as the total of component (A) and component (B). If the content is at least 0.01 part by weight it will tend to be easier to obtain sufficient sensitivity, and if the content is no greater than 10 parts by weight, there will be less of a tendency for an excess of component (E) to be deposited as extraneous material alter film formation.

<Other Components>

The photosensitive resin composition of this embodiment may also contain, if necessary, photopolymerizable compounds with at least one cationic polymerizable cyclic ether group in the molecule (oxetane compounds, etc.), cationic polymerization initiators, dyes such, as malachite green, photochromic agents such as tribromophenylsulfone and leuco crystal violet, thermal development inhibitors, plasticizers such as p-toluenesulfonamide, pigments, fillers, antifoaming agents, flame retardants, stabilizers, tackifiers, leveling agents, release promoters, antioxidants, aromas, imaging agents or thermal crosslinking agents. They may be used alone or in combinations of two or more. Their contents are preferably about 0.01 to 20 parts by weight each, with respect to 100 parts by weight as the total of component (A) (the binder polymer) and component (B) (the photopolymerizable compound).

(Photosensitive Resin Composition Solution)

The photosensitive resin composition of this embodiment may be dissolved in an organic solvent for use as a solution with a solid content of about 30 to 60 wt % (coating solution). Examples of organic solvents include, methanol, ethanol, acetone, methyl ethyl ketone, methylcellosolve, ethylcellosolve, toluene, N,N-dimethylformamide, propylene glycol monomethyl ether, and mixtures of these solvents.

The coating solution may be coated onto the surface of a metal sheet or the like and dried to form a photosensitive resin composition layer composed of the photosensitive resin composition of this embodiment. Examples of metal sheets include copper, copper-based alloys, nickel, chromium, iron and iron-based alloys such as stainless steel, with copper, copper-based alloys and iron-based alloys being preferred.

The thickness of the photosensitive resin composition layer will differ depending on the purpose, but it is preferably about 1 to 100 pin as the post-drying thickness. The surface of the photosensitive resin composition layer opposite the metal sheet side may be covered with a protective film. As protective films there may be mentioned polymer films such as polyethylene and polypropylene.

(Photosensitive Element)

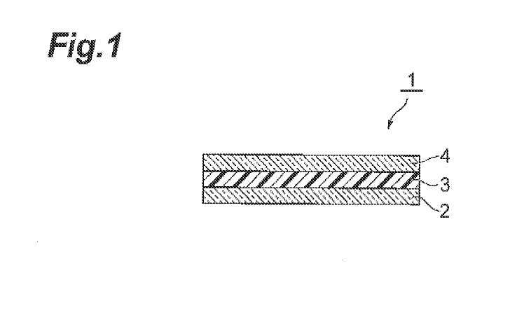

FIG. 1 is a schematic cross-sectional view showing a preferred embodiment of a photosensitive element 1 of the invention.

The photosensitive resin composition solution may be coated onto a support film 2 and dried to form a photosensitive resin composition layer 3 composed of the photosensitive resin composition on the support film 2. Thus, a photosensitive element 1 of this embodiment is obtained comprising the support film 2 and the photosensitive resin composition layer 3 formed on the support film.

The support film may be a polymer film having heat resistance and solvent resistance, such as polyethylene terephthalate, polypropylene, polyethylene or polyester, for example.

The thickness of the support film (polymer film) is preferably 1 to 100 μm, more preferably 5 to 50 μm and even more preferably 5 to 30 μm. If the thickness is less than 1 μm, the support film will tend to tear when it is released. If the thickness exceeds 100 μm, it will tend to be difficult to obtain sufficient resolution.

The photosensitive element may, if necessary, be provided with a protective film 4 covering the surface of the photosensitive resin composition layer 3 opposite the support film 2 side.

The protective film is preferably one whose adhesive force for the photosensitive resin composition layer is lower than the adhesive force of the support film for the photosensitive resin composition layer. The protective film is also preferably a low fisheye film. The term “fisheyes” refers to extraneous material, insoluble matter or oxidative degradation products of the materials that become incorporated into films during their production by heat-fusion, kneading, extrusion, biaxial stretching and casting of film materials, in other words, “low fisheyes” means few of the aforementioned extraneous material in the film.

Specifically, the protective filmm used may be a polymer film having heat resistance and solvent resistance, such as polyethylene terephthalate, polypropylene, polyethylene or polyester, for example. Commercially available products include ALPHAN MA-410 and E-200C by Oji Paper Co., Ltd., polypropylene films by Shin-Etsu Film. Co., Ltd. and polyethylene terephthalate films of the PS series such as PS-25 by Teijin, Ltd. The protective film may be the same material as the support film.

The thickness of the protective film is preferably 1 to 100 μm, more preferably 5 to 50 μm, even more preferably 5 to 30 μm and most preferably 15 to 30 μm. If the thickness is less than 1 μm the protective film will tend to be more prone to tearing during lamination of the photosensitive resin composition layer and the protective film on the substrate, while if it is greater than 100 μm the effect will tend to be insufficient in terms of cost reduction.

Coating of the photosensitive resin composition solution on the support film may be accomplished by a publicly known method such as, for example, roll coating, comma coating, gravure coating, air knife coating, die coating, bar coating or the like.

Drying of the solution is preferably carried out for about 5 to 30 minutes at 70° C. to 150° C. After drying, the amount of residual organic solvent in the photosensitive resin composition layer is preferably no greater than 2 wt % from the viewpoint of preventing diffusion of the organic solvent in subsequent steps.

The thickness of the photosensitive resin composition layer in the photosensitive element will differ depending on the use, but the post-drying thickness is preferably 1 to 100 μm, more preferably 1 to 50 μm and even more preferably 5 to 40 μm. A thickness of less than 1 μm will tend to hamper industrial coating, while a thickness of greater than 100 μm will tend to make it difficult to obtain sufficient adhesiveness and resolution.

The transmittance of the photosensitive resin composition layer for ultraviolet rays is preferably 5-75%, more preferably 10-65% and most preferably 15-55%, for ultraviolet rays with a wavelength of 405 nm. If the transmittance is less than 5% it will tend to be difficult to obtain sufficient adhesiveness, while if it exceeds 75% it will tend to be difficult to obtain sufficient resolution.

The transmittance may be measured using a UV spectrometer. The UV spectrometer may be a Model 228A W Beam spectrophotometer by Hitachi, Ltd.

The photosensitive element may also comprise interlayers such as a cushion layer, adhesive layer, photoabsorbing layer and gas barrier layer.

The obtained photosensitive element may be stored as a sheet or as a roll wound up on a winding core. When wound up as a roll, it is preferably wound in such a manner that the support film is on the outer side. Examples for the winding core include plastics such as polyethylene resin, polypropylene resin, polystyrene resin, polyvinyl chloride resin and ABS resin (acrylonitrile-butadiene-styrene copolymer). An edge separator is preferably situated at the edges of the photosensitive element roll obtained in this manner, from the viewpoint of edge protection, while from the viewpoint of preventing edge fusion, a moisture-proof edge separator is preferably situated. The packaging method is preferably one that involves bundling in a black sheet with low moisture permeability.

(Method for Forming Resist Pattern)

The photosensitive resin composition may be used to form a resist pattern. The method for forming a resist pattern according to this embodiment comprises (i) a lamination step in which a photosensitive resin composition layer formed using the aforementioned photosensitive resin composition is laminated on a board, (ii) an exposure step in which prescribed sections of the photosensitive resin composition layer are irradiated with active light rays for exposure and curing of the prescribed sections, and (iii) a developing step in which the sections other than the prescribed sections of the photosensitive resin composition layer are removed from the substrate to form a resist pattern composed of the cured photosensitive resin composition on the substrate.

(i) Lamination Step

First, a photosensitive resin composition layer formed using a photosensitive resin composition is laminated on a substrate. The substrate used may be a substrate cult-laming board) comprising an insulating layer and a conductive layer formed on the insulating layer.

Lamination of the photosensitive resin composition layer on the substrate is carried out, for example, by removing the protective film from the photosensitive element and then heating the photosensitive resin composition layer of the photosensitive element while contact bonding it to the substrate. This yields a laminated body comprising the substrate, photosensitive resin composition layer and support film, laminated in that order.

The lamination operation is preferably carried out under reduced pressure from the viewpoint of adhesiveness and following property. The heating of the photosensitive resin composition layer and/or substrate during contact bonding is preferably carried out at a temperature of 70° C. to 130° C., with contact bonding at a pressure of about 0.1 to 1.0 MPa (about 1 to 10 kgf/cm²), although there is no particular restriction to these conditions. If the photosensitive resin composition layer is heated at 70° C. to 130° C. it is not necessary to subject the substrate to preheating beforehand, but the substrate may nevertheless be preheated for further improved laminating properties.

(ii) Exposure Step

Next, prescribed sections of the photosensitive resin composition layer on the substrate are irradiated with active light rays for exposure and curing of those prescribed sections. When the support film on the photosensitive resin composition layer is transparent to the active light rays, the active light rays can be irradiated through the support film. When the support film blocks active light rays, however, the photosensitive resin composition layer is irradiated with the active light rays after removal of the support film.

The method of exposure may be a method of irradiation with active light rays into an image form, through a negative or positive mask pattern known as artwork (mask exposure method). The active light rays may also be irradiated into an image form by a direct writing exposure method such as LDI (Laser Direct Imaging) exposure or DLP (Digital Light Processing) exposure.

The photosensitive resin composition of the invention can be suitably used in a direct writing exposure method. That is, according to a preferred mode of the invention, a photosensitive resin composition comprising a binder polymer having a (meth)acrylic acid-based structural unit, with a dispersity of no greater than 1.6, a photopolymerizable compound, a photopolymerization initiator and a sensitizing dye, is used in direct writing exposure.

The light source for the active light rays may be a known light source, such as a carbon arc lamp, mercury vapor arc lamp, high-pressure mercury lamp, xenon lamp or a gas laser such as an argon laser, a solid laser such as a YAG laser, a semiconductor laser and the like, which efficiently emits ultraviolets rays or visible light ray.

The wavelength of the active light rays (exposure wavelength) is preferably in the range of 340 to 430 nm and more preferably in the range of 350 to 420 nm, from the viewpoint of more reliably obtaining the effect of the invention.

(iii) Developing Step

In addition, by removing the sections of the photosensitive resin composition layer from the substrate other than the aforementioned prescribed sections, a resist pattern composed of the cured photosensitive resin composition is formed on the substrate. When a support film is present on the photosensitive resin, composition layer, the sections (unexposed sections) other than the prescribed sections (exposed sections) are removed after removing the support film (development). The development process may be wet development or dry development, but wet development is more widely used.

For wet development, a developing solution corresponding to photosensitive resin composition is used for development by a known development process. The development process may be a method employing, for example, a dip system, paddle system, spray system, or brushing, slapping, scrapping, reciprocal dipping or the like, although a high-pressure spray system is most suitable from the viewpoint of improving the resolution. Development may also be carried out with a combination of two or more of the aforementioned methods.

The developing solution may be an aqueous alkali solution, aqueous developing solution, organic solvent-based developing solution, or the like.

Using an aqueous alkali solution as the developing solution is safe and stable, and results in satisfactory operativity. Examples of bases for the aqueous alkali solution include alkali hydroxides such as hydroxides of lithium, sodium or potassium; alkali carbonates such as carbonates or bicarbonates of lithium, sodium, potassium or ammonium; alkali metal phosphates such as potassium phosphate and sodium phosphate; and alkali metal pyrophosphates such as sodium pyrophosphate and potassium pyrophosphate.

The aqueous alkali solution is preferably a dilute solution of 0.1 to 5 wt % sodium carbonate, a dilute solution of 0.1 to 5 wt % potassium carbonate, a dilute solution of 0.1 to 5 wt % sodium hydroxide, a dilute solution of 0.1 to 5 wt % sodium tetraborate, or the like. The pH of the aqueous alkali solution is preferably in the range of 9-11, and the concentration is adjusted as appropriate for the alkali developing property of the photosensitive resin composition layer. The aqueous alkali solution may also contain added surfactants, antifoaming agents, and small amounts of organic solvent to accelerate development.

An aqueous developing solution may be, for example, a developing solution comprising water or an aqueous alkali solution and one or more different organic solvents. Examples of bases for the aqueous alkali solution, other than those already mentioned above, also include borax, sodium metasilicate, tetramethylammonium hydroxide, ethanolamine, ethylenediamine, diethylenetriamine, 2-amino-2-hydroxymethyl-1,3-propanediol, 1,3-diamino-2-propanol and morpholine. The pH of the aqueous developing solution is preferably as low as possible within a range allowing sufficient development, and it is preferably pH 8 to 12 and more preferably pH 9 to 10.

Examples of organic solvents to be used in the aqueous developing solution include acetone, ethyl acetate, alkoxyethanols with C1-4 alkoxy groups, ethyl alcohol, isopropyl alcohol, butyl alcohol, diethyleneglycol monomethyl ether, diethyleneglycol monoethyl ether, diethyleneglycol monobutyl ether and the like. They may be used alone or in combinations of two or more. The concentration of the organic solvent in the aqueous developing solution is usually preferred to be 2 to 90 wt %. The concentration may be adjusted as appropriate to match the alkali developing property. The aqueous developing solution may also contain small amounts of added surfactants, antifoaming agents and the like.

Examples of organic solvent-based developing solutions include organic solvents such as 1,1,1-trichloroethane, N-methylpyrrolidone, N,N-dimethylformamide, cyclohexanone, methyl isobutyl ketone and γ-butyrolactone. Water is preferably added to these organic solvents in a range of 1 to 20 wt % for anti-flammability.

After removing the unexposed sections, if necessary, heating at about 60° C. to 250° C. or exposure at about 0.2-10 J/cm² may be carried out for further curing of the resist pattern.

(Method for Manufacturing Printed Wiring Board)

A printed wiring board can be produced by etching or plating a substrate on which a resist pattern has been formed by the method described above. The etching or plating of the substrate is carried out on the conductive layer of the substrate using the formed resist pattern as a mask.

The etching solution used for etching may be, for example, a cupric chloride solution, ferric chloride solution, alkali etching solution, hydrogen peroxide etching solution or the like, with a ferric chloride solution being preferred for a more satisfactory etch factor.

The method used for plating may be, for example, copper plating such as copper sulfate plating or copper pyrophosphate plating, solder plating such as high throwing solder plating, nickel plating such as Watt bath (nickel sulfate-nickel chloride) plating or nickel sulfamate plating, or gold plating such as hard gold plating or soft gold plating.

After completion of the etching or plating, the resist pattern is released, for example, with an aqueous solution of stronger alkalinity than the aqueous alkali solution used for development. The strongly alkaline aqueous solution used here may be, for example, a 1 to 10 wt % sodium hydroxide aqueous solution, a 1 to 10 wt % potassium hydroxide aqueous solution or the like. Among them, a 1 to 10 wt % sodium hydroxide aqueous solution or a potassium hydroxide aqueous solution is preferably used, and a 1 to 5 wt % sodium hydroxide aqueous solution or potassium hydroxide aqueous solution is more preferably used.

The releasing system for the resist pattern may be a dipping system, spraying system or the like, which may be used either alone or in combinations. The printed wiring board on which the resist pattern has been formed may be a multilayer printed wiring board, and it may also have small through-holes.

The photosensitive resin composition of the invention can be suitably used for manufacture of a printed wiring board. That is, a preferred mode of the invention is the use of a photosensitive resin composition comprising a binder polymer having a (meth)acrylic acid-based structural unit, with a dispersity of no greater than 1.6, a photopolymerizable compound, a photopolymerization initiator and a sensitizing dye, for manufacture of a printed wiring board.

### Examples

The present invention will now be explained in greater detail by examples. However, the present invention is not limited to the examples described below.

(Preparation of Solutions for Photosensitive Resin Compositions)

Components (A) to (E) listed in Table 2 and Table 3 were combined in the amounts (g) shown in the tables, to prepare photosensitive resin composition solutions for Examples 1 to 12 and Comparative Examples 1 to 11. The amounts of component (A) shown in Table 2 and Table 3 are the weights of the nonvolatile portion (solid content). The details for each of the components in Table 2 and Table 3 are as follows.

<(A) Binder Polymer>

The polymerizable monomer weight ratios, acid values, weight-average molecular weights and dispersities of binder polymers (A-1) to (A-9) are shown in Table 1.

[Binder Polymers (A-1) and (A-2)]

As binder polymers (A-1) and (A-2) there were used polymers synthesized by living radical polymerization (precision polymerization), The synthesis method may be the method described in Patent Literature 5 (JP 2009-19165 A), for example.

[Synthesis of Binder Polymer (A-3)]

As “solution a” there was prepared a solution obtained by mixing 150 g of methacrylic acid, 125 g of benzyl methacrylate, 25 g of methyl methacrylate and 200 g of styrene (weight ratio: 30/25/5/40), as polymerizable monomers, with 9.0 g of azobisisobutyronitrile.

As “solution b” there was prepared a solution obtained by dissolving 1.2 g of azobisisobutyronitrile in 100 g of a liquid mixture comprising 60 g of methylcellosolve and 40 g of toluene (weight ratio: 3:2).

Into a flask equipped with a stirrer, reflux condenser, thermometer, dropping funnel and nitrogen gas inlet tube there was charged 450 g of a liquid mixture comprising 270 g of methylcellosolve and 180 g of toluene (weight ratio=3:2), and heating was performed while stirring and blowing nitrogen gas into the flask, raising the temperature to 80° C.

Solution a was added dropwise to the liquid mixture in the flask over a period of 4 hours, and was then warmed at 80° C. for 2 hours while stirring. Next, solution b was added dropwise to the solution in the flask over a period of 10 minutes, and the solution in the flask was warmed at 80° C. for 3 hours while stirring. The solution in the flask was further heated to 90° C. over a period of 30 minutes, warmed at 90° C. for 2 hours, and then cooled to obtain a solution of a binder polymer (A-3).

The nonvolatile portion (solid portion) of the binder polymer (A-3) was 47.8 wt, the weight-average molecular weight was 40,000, and the acid value was 196 mgKOH/g.

The weight-average molecular weight was measured by gel permeation chromatography (GPC), and calculation was performed using a standard polystyrene calibration curve. The GPC conditions were as follows,

### GPC Conditions

Pump: Hitachi L-6000 (trade name of Hitachi, Ltd.).

Column: Gelpack GL-R420, Gelpack GL-R430, Gelpack GL-R440 (all trade names of Hitachi Chemical Co., Ltd.).

Eluent: tetrahydrofuran
Measuring temperature: 40° C.
Flow rate: 2.05 mL/min
Detector: Hitachi L-3300 RI (trade name of Hitachi, Ltd.).

[Synthesis of Binder Polymers (A-4) to (A-9)]

The polymerizable monomers used were the materials listed in Table 1 in the weight ratios shown in the same table, to obtain solutions of binder polymers (A-4) to (A-9) in the same manner as the solution of binder polymer (A-3).

The polymerizable monomers weight ratios, acid values, weight-average molecular weights and dispersities of binder polymers (A-1) to (A-9) are shown in Table 1.

TABLE 1

| | | Polymerizable monomers weight ratio | | | | | | |
|---|---|---|---|---|---|---|---|---|
| | Methacrylic | Benzyl | Methyl | Butyl | | Acid value | | |
| | acid | methacrylate | methacrylate | methacrylate | Styrene | (mgKOH/g) | Mw | Dispersity |
| (A-1) | 27 | 23 | 5 | — | 45 | 176 | 40000 | 1.53 |
| (A-2) | 30 | 25 | 5 | — | 40 | 196 | 40000 | 1.47 |
| (A-3) | 30 | 25 | 5 | — | 40 | 196 | 40000 | 2.1 |
| (A-4) | 25 | — | 25 | 50 | — | 163 | 40000 | 2.1 |
| (A-5) | 25 | — | 50 | — | 25 | 163 | 40000 | 2.1 |
| (A-6) | 30 | 25 | — | — | 45 | 195 | 43000 | 2.1 |
| (A-7) | 25 | — | 50 | — | 25 | 163 | 55000 | 2.1 |
| (A-8) | 25 | — | 50 | — | 25 | 163 | 30000 | 2.1 |
| (A-9) | 30 | 25 | 5 | — | 40 | 196 | 40000 | 1.8 |

### <(B) Photopolymerizable Compounds>

TMPT21E (sample name of Hitachi Chemical Co., Ltd.): EO modified trimethylolpropane trimethacrylate (average 21 mol ethylene oxide addition product)
FA-321M: 2,2-bis(4-(Methacryloxypentaethoxy)phenyl)prop (trade name of Hitachi Chemical Co., Ltd.)
FA-024M (trade name of Hitachi Chemical Co., Ltd.): Vinyl compound of the general formula (4) in which R⁷ and R⁸=methyl, r₃=6 (mean value) and s₂+s₃=12 (mean value).
FA-023M (trade name of Hitachi Chemical Co., Ltd.): Vinyl compound of the general formula (3) in which R⁵ and R⁶=ethyl, r₁+r₂=6 (mean value) and s₁=12 (mean value).
M-114 (trade name of Toagosei Co., Ltd.): 4-normal-Nonylphenoxyoctaethylene glycol acrylate
BPE-200 (trade name of Shin-Nakamura Chemical Co., Ltd.): 2,2-bis[4-((Meth)acryloyloxydiethoxy)phenyl]propane

<(C) Photopolymerization Initiator>

B-CIM (trade name of Hampford Co.): 2,2′-bis(2-Chlorophenyl)-4,4′,5,5′-tetraphenylbisimidazole

<(D) Sensitizing Dyes>

PYR-1 (product of Nippon Chemical Industrial Co., Ltd.): 1-Phenyl-3-(4-methoxy styryl)-5-(4-methoxyphenyl)pyrazoline
DBA (trade name of Kawasaki Kasei Chemicals, Ltd.): 9,10-Dibutoxyanthracene
J205 (trade name of Nihon Jyoryu Kogyo Co., Ltd.): Triphenylamine derivative represented by the following formula (10).

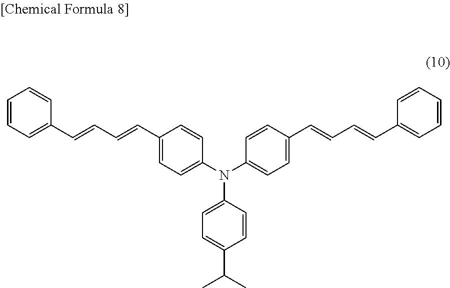 [SMILES: CC(C)c1ccc(N(c2ccc(/C=C/C=C/c3ccccc3)cc2)c2ccc(/C=C/C=C/c3ccccc3)cc2)cc1]

EAB (trade name of Hodogaya Chemical Co., Ltd.): 4,4′-bis(Diethylamino)benzophenone
DETX (trade name of Nippon Kayaku Co., Ltd.): 2,4-Diethylthioxanthone
C102 (trade name of Acros Co.): 9-Methyl-2,3,6,7-tetrahydro-1H, 5H, 11H-[1]benzopyrano[6,7,8-ij]quinolysin-11-one
ACR (trade name): 9-Monopentylaminoacridine
NF-MC (trade name of Nippon Chemical Industrial Co., Ltd.): 7-Diethylamino-4-methylcoumarin

<(E) Amine-Based Compound>

LCV: Leuco crystal violet (trade name of Yamada Chemical Co., Ltd.)

### <Dye>

MKG (trade name of Osaka Organic Chemical Industry, Ltd. Malachite Green

TABLE 2

| | | Example | | | | | | | | | | | |
|---|---|---|---|---|---|---|---|---|---|---|---|---|---|
| Component | | 1 | 2 | 3 | 4 | 5 | 6 | 7 | 8 | 9 | 10 | 11 | 12 |
| (A) | (A-1) | 58 | 58 | — | — | 58 | 58 | 58 | 58 | 58 | 58 | 58 | 58 |
| | (A-2) | — | — | 58 | 58 | — | — | — | — | — | — | — | — |
| (B) | TMPT21E | 10 | — | 10 | — | 10 | 10 | 10 | 10 | 10 | 10 | 10 | 10 |
| | FA-321M | 27 | 27 | 27 | 27 | 27 | 27 | 27 | 10 | 10 | 10 | 10 | 10 |
| | FA-024M | — | 10 | — | 10 | — | — | — | — | — | — | — | — |
| | M-114 | 5 | 5 | 5 | 5 | 5 | 5 | 5 | 5 | 5 | 5 | 5 | 5 |
| | BPE-200 | — | — | — | — | — | — | — | 17 | 17 | 17 | 17 | 17 |
| (C) | B-CIM | 3.7 | 3.7 | 3.7 | 3.7 | 3.7 | 3.7 | 3.7 | 3.7 | 3.7 | 3.7 | 3.7 | 3.7 |
| (D) | PYR-1 | 0.18 | 0.18 | 0.18 | 0.18 | — | — | — | 0.18 | — | — | — | — |
| | DBA | — | — | — | — | 0.65 | — | — | — | — | — | — | — |
| | J205 | — | — | — | — | — | 0.15 | — | — | — | — | — | — |
| | EAB | — | — | — | — | — | — | 0.4 | — | — | — | — | — |
| | DETX | — | — | — | — | — | — | — | — | 1.3 | — | — | — |
| | C102 | — | — | — | — | — | — | — | — | — | 0.3 | — | — |
| | ACR | — | — | — | — | — | — | — | — | — | — | 0.3 | — |
| | NF-MC | — | — | — | — | — | — | — | — | — | — | — | 0.8 |
| (E) | LCV | 0.5 | 0.5 | 0.5 | 0.5 | 0.5 | 0.5 | 0.5 | 0.5 | 0.5 | 0.5 | 0.5 | 0.5 |
| Dye | MKG | 0.03 | 0.03 | 0.03 | 0.03 | 0.03 | 0.03 | 0.03 | 0.03 | 0.03 | 0.03 | 0.03 | 0.03 |
| Solvent | Acetone | 9 | 9 | 9 | 9 | 9 | 9 | 9 | 9 | 9 | 9 | 9 | 9 |
| | Toluene | 5 | 5 | 5 | 5 | 5 | 5 | 5 | 5 | 5 | 5 | 5 | 5 |
| | Methanol | 5 | 5 | 5 | 5 | 5 | 5 | 5 | 5 | 5 | 5 | 5 | 5 |

TABLE 3

| | | Comparative Example | | | | | | | | | | |
|---|---|---|---|---|---|---|---|---|---|---|---|---|
| Component | | 1 | 2 | 3 | 4 | 5 | 6 | 7 | 8 | 9 | 10 | 11 |
| (A) | (A-3) | 58 | 58 | — | — | — | — | — | — | — | — | — |
| | (A-4) | — | — | 58 | 58 | — | — | — | — | — | — | — |
| | (A-5) | — | — | — | — | 56 | 56 | — | — | — | — | — |
| | (A-6) | — | — | — | — | — | — | 56 | 56 | — | — | — |
| | (A-7) | — | — | — | — | — | — | — | — | 54 | — | — |
| | (A-8) | — | — | — | — | — | — | — | — | — | 54 | — |
| | (A-9) | — | — | — | — | — | — | — | — | — | — | 58 |
| (B) | TMPT21E | 10 | — | 10 | — | — | — | — | — | — | — | 10 |
| | FA-321M | 27 | 27 | 27 | 27 | 44 | 34 | 44 | 34 | 46 | 46 | 27 |
| | FA-024M | — | 10 | — | 10 | — | — | — | — | — | — | — |
| | FA-023M | — | — | — | — | — | 10 | — | 10 | — | — | — |
| | M-114 | 5 | 5 | 5 | 5 | — | — | — | — | — | | 5 |
| (C) | B-CIM | 3.7 | 3.7 | 3.7 | 3.7 | 3.7 | 3.7 | 3.7 | 3.7 | 3.7 | 3.7 | 3.7 |
| (D) | PYR-1 | 0.18 | 0.18 | 0.18 | 0.18 | — | — | — | — | 0.2 | — | 0.18 |
| | DBA | — | — | — | — | — | — | — | — | — | 0.6 | — |
| | J205 | — | — | — | — | 0.15 | 0.15 | 0.15 | 0.15 | — | — | — |
| (E) | LCV | 0.5 | 0.5 | 0.5 | 0.5 | 0.3 | 0.3 | 0.3 | 0.3 | 0.5 | 0.3 | 0.5 |
| Dye | MKG | 0.03 | 0.03 | 0.03 | 0.03 | 0.03 | 0.03 | 0.03 | 0.03 | 0.03 | 0.03 | 0.03 |
| Solvent | Acetone | 9 | 9 | 9 | 9 | 9 | 9 | 9 | 9 | 10 | 9 | 9 |
| | Toluene | 5 | 5 | 5 | 5 | 5 | 5 | 5 | 5 | 7 | 5 | 5 |
| | Methanol | 5 | 5 | 5 | 5 | 5 | 5 | 5 | 5 | 3 | 5 | 5 |

(Photosensitive Element)

Each of the solution of the photosensitive resin composition was evenly coated onto polyethylene terephthalate film with a thickness of 16 μm “HTF-01”, trade name of Teijin, Ltd.) and dried at 70° C. and 110° C. with a hot air convection current drier, to form a photosensitive resin composition layer with a post-drying thickness of 25 μm. A protective film (“NF-15”, trade name of Tamapoly Co., Ltd.) was attached onto the photosensitive resin composition layer to obtain a photosensitive element comprising a polyethylene terephthalate film (support film), photosensitive resin composition layer and protective film, laminated in that order.

(Multilayer Substrate)

The copper surface of a copper-clad laminate (“MCL-E-679F”, trade name of Hitachi Chemical Co., Ltd.) comprising a glass epoxy material and a copper foil (thickness: 16 μm) formed on both sides thereof, was roughened using a CZ treatment solution by Mec Co., Ltd. The roughened copper substrate (hereunder referred to simply as “substrate”) was heated to raise the temperature to 80° C., and then each of the photosensitive elements of Examples 1 to 12 and Comparative Examples 1 to 11 was laminated (layered) on the copper surface of the substrate. The lamination was accomplished under conditions with a temperature of 1.20° C. and a lamination pressure of 4 kgf/cm², while removing the protective film, so that the photosensitive resin composition layer of each photosensitive element was closely bonded to the copper surface of the substrate. Thus, a multilayer substrate was obtained comprising a photosensitive resin composition layer and polyethylene terephthalate film laminated on the copper surface of a substrate.

(Evaluation of Sensitivity)

The obtained multilayer substrate was allowed to cool, and upon reaching 23° C., a phototool having a 41-step tablet with a density region of 0.00-2.00, a density step of 0.05, a tablet size of 20 mm×187 mm and a step size of 3 mm×12 ram, was firmly attached to the polyethylene terephthalate film of the multilayer substrate. A “DE-1UH” (trade name) direct writing exposure device by Hitachi Via Mechanics, Ltd., employing a violet laser diode with a wavelength of 405 nm as the light source, was used for exposure of the photosensitive resin composition layer through the phototool and polyethylene terephthalate film, at an energy dose (exposure dose) of 80 mJ/cm². The measurement of illuminance was performed using an ultraviolet illuminometer employing a 405 nm-responding probe (“UIT-150”, trade name of Ushio Inc).

Following exposure, the polyethylene terephthalate film was released from the multilayer substrate to lay bare the photosensitive resin composition layer, and 1 wt % aqueous sodium carbonate was sprayed at 30° C. for 24 seconds, to remove the unexposed sections. Thus was formed a cured film comprising a cured photosensitive resin composition on the copper surface of a substrate. The number of remaining steps of the step tablet (step number) obtained as the photocured film was then counted to evaluate the sensitivity of the photosensitive resin composition. The sensitivity is represented as this number of steps, with a greater number of steps indicating more satisfactory sensitivity. The results are shown in Table 5 and Table 6.

(Evaluation of Resolution and Adhesiveness)

A drawing pattern with a line width (L)/space width (S) (hereunder, “L/S”) of 3/3 to 30/30 (units: μm) was used for exposure (drawing) of the photosensitive resin composition layer on the multilayer substrate at an energy dose for 16 steps remaining on a 41 step tablet. Following exposure, developing treatment was carried out in the same manner as for evaluation of the sensitivity.

After development, the resolution and adhesiveness were evaluated by the minimum among the line width/space width values for resist patterns formed with cleanly removed space sections (unexposed sections), and without meandering or defect of the line sections (exposed sections). A smaller numerical value indicates more satisfactory resolution and adhesiveness. The results are shown in Table 5 and Table 6.

(Evaluation of Resist Shape)

During evaluation of the resolution and adhesiveness, the obtained resist shape cross-sectional shape of the resist pattern) was observed using a Hitachi S-500A scanning electron microscope, if the resist shape is trapezoidal or inverted trapezoidal, or the resist has bottom trailing or cracking, the circuit formed by the subsequent etching treatment or plating treatment will tend to exhibit shorting or wire breakage. The resist shape is therefore preferably rectangular, with no bottom trailing or cracking of the resist. The term “cracking” means that cracks or fissures have occurred in the line sections (exposed sections) of the resist pattern, or that defect or fracturing has also taken place in the line sections. An evaluation of “A” was assigned if the resist shape was rectangular and no bottom trailing or cracking was found in the resist, and an evaluation of “B” was assigned if bottom trailing of the resist was observed. The results are shown in Table and Table 6.

(Evaluation of Release Property)

Each photosensitive element was laminated on the copper clad laminate (substrate) and subjected to exposure and development under the conditions shown in Table 4, to fabricate a test piece (40 mm×50 mm) having a cured film formed on the substrate. The test piece was allowed to stand for a day and a night at room temperature, and was then released under the conditions shown in Table 4. The release time (seconds) was evaluated as the time from initiating stirring until the cured film was completely released and removed from the substrate. The release strip size after release was visually observed and evaluated based on the scale shown below. A shorter release time and smaller release strip size indicates a more satisfactory release property. The results are shown in Table 5 and Table 6.

### Release Strip Size

L: Sheet form

M: 30 to 40 mm square

S: Smaller than 30 mm square

TABLE 4

| Process | Conditions |
|---|---|
| Exposure | Exposure device: “DE-1UH” direct writing exposure device |
| | by Hitachi Via Mechanics, Ltd. |
| | (Light source: 405 nm violet laser diode) |
| | Exposure dose: 80 mJ/cm² |
| Development | Developing solution: 1 wt % aqueous sodium carbonate |
| | solution |
| | Solution temperature: 30° C. |
| | Spray system |
| Release | Release solution: 3 wt % aqueous sodium hydroxide |
| | solution |
| | Solution temperature: 50° C. |
| | With dip stirring |

TABLE 5

| | Example | | | | | | | | | | | |
|---|---|---|---|---|---|---|---|---|---|---|---|---|
| | 1 | 2 | 3 | 4 | 5 | 6 | 7 | 8 | 9 | 10 | 11 | 12 |
| Film thickness | 25 | 25 | 25 | 25 | 25 | 25 | 25 | 25 | 25 | 25 | 25 | 25 |
| (μm) | | | | | | | | | | | | |
| Developing | 26 | 25 | 25 | 25 | 25 | 25 | 25 | 32 | 30 | 32 | 33 | 32 |
| time (sec) | | | | | | | | | | | | |
| Sensitivity | 16 | 16 | 16 | 16 | 16 | 16 | 14 | 15 | 14 | 14 | 14 | 14 |
| (no. of steps) | | | | | | | | | | | | |
| Resolution/ | 7 | 7 | 7 | 7 | 7 | 7 | 8 | 6 | 7 | 7 | 7 | 7 |
| adhesiveness | | | | | | | | | | | | |
| (μm) | | | | | | | | | | | | |
| Resist shape | A | A | A | A | A | A | A | A | A | A | A | A |
| Release time | 82 | 81 | 80 | 80 | 81 | 82 | 82 | 89 | 88 | 86 | 85 | 86 |
| (sec) | | | | | | | | | | | | |
| Release | S | S | S | S | S | S | S | S | S | S | S | S |
| strip size | | | | | | | | | | | | |

TABLE 6

| | Comparative Example | | | | | | | | | | |
|---|---|---|---|---|---|---|---|---|---|---|---|
| | 1 | 2 | 3 | 4 | 5 | 6 | 7 | 8 | 9 | 10 | 11 |
| Film thickness (μm) | 25 | 25 | 25 | 25 | 25 | 25 | 25 | 25 | 25 | 25 | 25 |
| Developing time | 20 | 21 | 17 | 16 | 14 | 14 | 17 | 17 | 12 | 13 | 18 |
| (sec) | | | | | | | | | | | |
| Sensitivity | 16 | 16 | 16 | 16 | 16 | 16 | 15 | 15 | 17 | 16 | 16 |
| (no. of steps) | | | | | | | | | | | |
| Resolution/ | 10 | 10 | 14 | 14 | 14 | 14 | 12 | 10 | 15 | 15 | 9 |
| adhesiveness (μm) | | | | | | | | | | | |
| Resist shape | B | B | B | B | B | B | B | B | B | B | B |
| Release time (sec) | 80 | 81 | 82 | 80 | 40 | 42 | 78 | 80 | 40 | 42 | 78 |
| Release strip size | S | S | S | S | S | S | S | S | S | S | S |

As clearly seen in Table 5 and Table 6, the photosensitive resin compositions of Examples 1 to 12 were satisfactory in terms of all of the properties of sensitivity, resolution, adhesiveness, resist shape, post-curing release property.

### INDUSTRIAL APPLICABILITY

The photosensitive resin composition of the invention is applied as a material to form a resist pattern for manufacture of a printed wiring board. In particular, since the photosensitive resin composition is satisfactory in terms of all of the properties of sensitivity, resolution, adhesiveness, resist shape and post-curing release property, it can be suitably used to form a resist pattern for manufacture of a printed wiring board with fine, high-density wiring, such as a high-density package board.

### REFERENCE SIGNS LIST

1: Photosensitive element, 2: support film, 3: photosensitive resin composition layer, 4: protective film.

1. A photosensitive resin composition comprising:
a binder polymer having a (meth)acrylic acid-based structural unit, with a dispersity of no greater than 1.6,
a photopolymerizable compound,
a photopolymerization initiator, and
a sensitizing dye.

2. The photosensitive resin composition according to claim 1, wherein the binder polymer further has a structural unit based on at least one type of polymerizable monomer selected from the group consisting of benzyl (meth)acrylate, benzyl (meth)acrylate derivatives, styrene and styrene derivatives.

3. The photosensitive resin composition according to claim 1, wherein the acid value of the binder polymer is 90 to 250 mgKOH/g.

4. The photosensitive resin composition according to claim 1, wherein the weight-average molecular weight of the binder polymer is 10000 to 100000.

5. The photosensitive resin composition according to claim 4, wherein the photopolymerizable compound includes a bisphenol A-based di(meth)acrylate compound.

6. The photosensitive resin composition according to claim 1, wherein the photopolymerization initiator includes a 2,4,5-triarylimidazole dimer.

7. The photosensitive resin composition according to claim 1, which further comprises an amine-based compound.

8. A photosensitive element comprising a support film and a photosensitive resin composition layer formed on the support film using the photosensitive resin composition according to claim 1.

9. A method for forming a resist pattern, comprising:
a lamination step in which a photosensitive resin composition layer formed using the photosensitive resin composition according to claim 1 is laminated on a substrate,
an exposure step in which prescribed sections of the photosensitive resin composition layer are irradiated with active light rays for exposure and curing of the prescribed sections, and
a developing step in which the sections other than the prescribed sections of the photosensitive resin composition layer are removed from the substrate to form a resist pattern composed of the cured photosensitive resin composition on the substrate.

10. The method for forming a resist pattern according to claim 9, wherein the wavelength of the active light rays is in the range of 340 to 430 nm.

11. A method for manufacturing a printed wiring board, comprising a step of etching or plating a substrate having a resist pattern formed by the method according to claim 9.

12. A method for manufacturing a printed wiring board, comprising a step of etching or plating a substrate having a resist pattern formed by the method according to claim 10.
